(19) United States
(12) Patent Application Publication
(10) Pub. No.: US 2006/0268625 A1
(43) Pub. Date: Nov. 30, 2006

(54) Semiconductor integrated circuit and microcomputer

(76) Inventors: Yoshifumi Imaizumi, Tokyo (JP); Toyohiro Shimogawa, Tokyo (JP); Takayasu Ito, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/441,088

(22) Filed: May 26, 2006

(30) Foreign Application Priority Data
May 27, 2005 (JP) 2005-156117

(51) Int. Cl. G11C 7/10

(52) U.S. Cl. 365/189.01

(57) ABSTRACT

A technique for preventing circuit elements from being deteriorated or broken due to power-off is provided. A semiconductor memory is provided which includes a memory portion obtained by arranging electrically rewritable nonvolatile memory cells in array and a high voltage generation circuit capable of generating high voltage supplied to the memory portion. A power supply circuit and a control circuit are provided. The power supply circuit is for generating supply voltage for operating the semiconductor memory. The control circuit is for interrupting power supply from the power supply circuit to the semiconductor memory after the output voltage level of the high voltage generation circuit is lowered. After the output voltage level of the high voltage generation circuit is lowered, power supply from the power supply circuit to the semiconductor memory is interrupted. This prevents circuit elements from being deteriorated or broken due to power-off.

### CROSS-REFERENCE TO RELATED APPLICATION

The present application claims priority from Japanese patent application No. 2005-156117 filed on May 27, 2005, the content of which is hereby incorporated by reference into this application.

### BACKGROUND OF THE INVENTION

The present invention relates to a semiconductor integrated circuit and, in particular, to an improvement on a power-off technique in it. For example, the invention relates to a technique effectively applicable to a microcomputer that incorporates an electrically rewritable nonvolatile flash memory.

There are EEPROMs (Electrically Erasable and Programmable Read Only Memories) in which stored data is electrically erasable and writable. There are flash memories (flash EEPROMs) whose gate oxide film is constructed based on floating gate memory cells composed of a tunnel oxide film as in EPROMs, and in which stored data is electrically erasable in a lump by predetermined blocks. (Refer to Patent Document 1, for example.) In a flash memory, various types of power are generated by a power supply circuit for operating memory cell arrays or their peripheral circuits. Especially, in a flash memory, high voltage is required for erasing and information alteration. This high voltage is generated by such a high voltage generation circuit as charge pump, aside from supply voltage for the flash memory itself. (Refer to Patent Document 2, for example.) Such a flash memory is incorporated into a single-chip microcomputer. (Refer to Patent Document 3, for example.)

[Patent Document 1] Japanese Unexamined Patent Publication No. Hei 7(1995)-147098

[Patent Document 2] Japanese Unexamined Patent Publication No. 2001-85633

[Patent Document 3] Japanese Unexamined Patent Publication No. Hei 5(1993)-266219 corresponding U.S. Pat. No. 5,581,503

### SUMMARY OF THE INVENTION

When a single-chip microcomputer is in standby mode, power supply to its flash memory as nonvolatile memory is interrupted. Interruption of power supply to the flash memory is instructed by the central processing unit (CPU) in the microcomputer. The present inventors gave consideration to interruption of power supply to a flash memory. As a result, it was found that there was a possibility that the logic for a path for discharging high voltage might be made inconsistent by interruption of power supply to a flash memory. Also, it was found that this would cause deterioration in or breakage of circuit elements. More specific description will be given. It will be assumed that, when a charge pump is in operation, power supply to a flash memory is interrupted and the logic for a path for discharging high voltage becomes inconsistent. In this case, voltage is discharged through a low-breakdown voltage MOS transistor or the like, and this can result in deterioration in or breakage of the MOS transistor.

An advantage of the invention is to provide a technique for preventing circuit elements from being deteriorated or broken due to power-off.

The above and other advantages and novel features of the invention will be apparent from the description in this specification and the accompanying drawings.

The following is a brief description of the gist of the representative elements of the invention laid open in this application.

(1) A semiconductor integrated circuit including: a semiconductor memory having a memory portion constructed by arranging electrically rewritable nonvolatile memory cells in array and a high voltage generation circuit capable of generating high voltage supplied to the memory portion; and a power supply circuit for generating supply voltage for operating the semiconductor memory, in which the semiconductor integrated circuit is capable of interrupting power supply from the power supply circuit to the semiconductor memory according to a power-off signal. This semiconductor integrated circuit is provided with a control circuit for interrupting power supply from the power supply circuit to the semiconductor memory after the output voltage level of the high voltage generation circuit is lowered according to the power-off signal.

According to the above-mentioned means, the control circuit operates as follows: after the output voltage level of the high voltage generation circuit is lowered according to the power-off signal, it interrupts power supply from the power supply circuit to the semiconductor memory. This prevents circuit elements from being deteriorated or broken due to power-off.

(2) At this time, the control circuit can be so constructed that it includes a delay circuit. The delay circuit is for delaying the power-off signal so that the following is implemented: after the output voltage level of the high voltage generation circuit is lowered according to the power-off signal, power supply from the power supply circuit to the semiconductor memory is interrupted.

(3) An amount of delay of the power-off signal can be set in the delay circuit based on the time from the time when the power-off signal is asserted to the time when the output voltage level of the high voltage generation circuit is lowered to a predetermined voltage level.

(4) A semiconductor integrated circuit including: a semiconductor memory having a memory portion constructed by arranging electrically rewritable nonvolatile memory cells in array and a high voltage generation circuit capable of generating high voltage supplied to the memory portion; and a power supply circuit for generating supply voltage for operating the semiconductor memory, in which the semiconductor integrated circuit is capable of interrupting power supply from the power supply circuit to the semiconductor memory according to a power-off signal. This semiconductor integrated circuit can be provided with: a sensing circuit capable of sensing that the output voltage of the high voltage generation circuit has been lowered to a predetermined voltage level or below according to the power-off signal; and a logic gate for transmitting the power-off signal to the power supply circuit based on the result of sensing by the sensing circuit.

According to the above-mentioned means, the sensing circuit senses that the output voltage of the high voltage generation circuit has been lowered to a predetermined voltage level or below according to the power-off signal. The logic gate transmits the power-off signal to the power supply circuit based on the result of sensing by the sensing circuit. This prevents circuit elements from being deteriorated or broken due to power-off.

(5) At this time, the power supply circuit steps down external supply voltage supplied from external of the semiconductor integrated circuit, and can thereby generate supply voltage for operating the semiconductor memory.

(6) The semiconductor integrated circuit described under the item (5) above can be provided with: an external supply voltage detection circuit capable of detecting external supply voltage supplied from external of the semiconductor integrated circuit; and a determination circuit capable of determining drop in the external supply voltage based on the result of detection by the external supply voltage detection circuit. Thus, the semiconductor integrated circuit can be so constructed that power supply to the semiconductor memory is interrupted based on an output signal of the determination circuit or the power-off signal.

(7) A microcomputer including: a semiconductor memory having a memory portion constructed by arranging electrically rewritable nonvolatile memory cells in array and a high voltage generation circuit capable of generating high voltage supplied to the memory portion; a power supply circuit for generating supply voltage for operating the semiconductor memory; and a central processing unit capable of accessing the semiconductor memory, in which the microcomputer is capable of interrupting power supply from the power supply circuit to the semiconductor memory according to a power-off signal. The microcomputer is provided with: a sensing circuit capable of sensing that the output voltage of the high voltage generation circuit has been lowered to a predetermined voltage level or below according to the power-off signal; and a logic gate for transmitting the power-off signal to the power supply circuit based on the result of sensing by the sensing circuit.

According to the above-mentioned means, the sensing circuit senses that the output voltage of the high voltage generation circuit has been lowered to a predetermined voltage level or below according to the power-off signal. The logic gate transmits the power-off signal to the power supply circuit based on the result of sensing by the sensing circuit. This prevents circuit elements from being deteriorated or broken due to power-off.

(8) In the microcomputer described under the item (7) above, the power supply circuit steps down external supply voltage supplied from external of the semiconductor integrated circuit, and can thereby generate supply voltage for operating the semiconductor memory.

(9) The microcomputer described under the item (8) above is provided with: an external supply voltage detection circuit capable of detecting external supply voltage supplied from external of the semiconductor integrated circuit; and a determination circuit capable of determining drop in the external supply voltage based on the result of detection by the external supply voltage detection circuit. Power supply to the semiconductor memory can be interrupted based on an output signal of the determination circuit or the power-off signal.

(10) The semiconductor memory can be constructed as flash memory.

The following is a brief description of the gist of effects obtained by the representative elements of the invention laid open in this application.

Circuit elements can be prevented from being deteriorated or broken due to power-off.

### BRIEF DESCRIPTION OF THE DRAWINGS

FIG. 1 is a block diagram illustrating an example of the configuration of the principal part of a single-chip microcomputer as an example of a semiconductor integrated circuit according to the invention.

FIG. 2 is a block diagram illustrating an example of the overall configuration of the single-chip microcomputer.

FIG. 3 is a circuit diagram illustrating an example of the configuration of the memory portion included in the single-chip microcomputer.

FIG. 4 is a circuit diagram illustrating an example of the configuration of the charge pump included in the single-chip microcomputer.

FIG. 5 is a block diagram illustrating another example of the configuration of the principal part of a single-chip microcomputer.

### DETAILED DESCRIPTION OF THE PREFERRED EMBODIMENTS

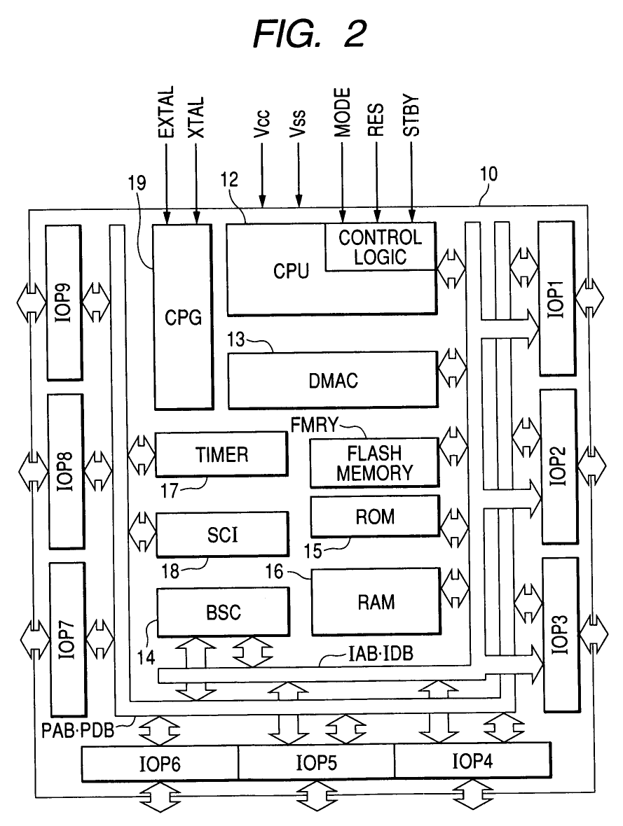

FIG. 2 illustrates a single-chip microcomputer as an example of a semiconductor integrated circuit according to the invention. The single-chip microcomputer 10 illustrated in the drawing is constructed of the functional blocks or modules listed below: flash memory FMRY, CPU 12, DMAC 13, a bus controller (BSC) 14, ROM 15, RAM 16, a timer 17, a serial communication interface (SCI) 18, first to ninth input/output ports IOP1 to IOP9, and a clock pulse generator (CPG) 19. It is formed as a semiconductor integrated circuit over one semiconductor substrate using publicly known semiconductor processing techniques.

The single-chip microcomputer 10 includes: a ground terminal Vss and a supply voltage terminal Vcc as power supply terminals for power supply from the outside of the chip; and includes, as other dedicated control terminals, a reset terminal RES, a standby terminal STBY, a mode control terminal MODE, and clock input terminals EXTAL and XTAL. These are external terminals. The clock pulse generator 9 generates system clock according to a quartz resonator, not shown, connected to the clock input terminals EXTAL and XTAL. The single-chip microcomputer 10 operates in synchronization with this system clock.

The functional blocks are connected with one another through internal buses. The internal buses consist of address buses, data buses, control buses for read signals, write signals, bus size signals, system clock, and the like. The internal address buses include IAB and PAB, and the internal data buses include IDB and PDB. The IAB and IDB are connected to the memory portion 22, CPU 12, ROM 15, RAM 16, bus controller 14, and some of the input/output ports IOP1 to IOP9. The PAB and PDB are connected to the bus controller 14, timer 17, SCI 18, and input/output ports IOP1 to IOP9. The IAB and PAB and the IDB and PDB are respectively interfaced with each other by the bus controller 14. The PAB and the PDB are solely used for register accessing in the functional blocks to which they are connected though the invention is not specially limited to this construction.

The input/output ports IOP1 to IOP9 are used both for input/output of external bus signals and for input/output of input/output signals of an input/output circuit. When they are used, their functions are selected by operation mode or software setting. External addresses and external data are respectively connected with the IAB and the IDB through buffer circuits, not shown, included in these input/output ports. The PAB and the PDB are used to read from and write to the built-in registers of the input/output ports, bus controller 14, and the like.

Both the internal buses and the external buses are of 16-bit bus width, and read/write operation is performed in one of byte size (8 bits) and in word size (16 bits). The external buses may be of 8-bit width.

When a system reset signal is applied to the reset terminal RES, the operation mode given at the mode control terminal MODE is taken in, and the single-chip microcomputer 10 is brought into reset state. The operation mode determines whether to enable/disable the built-in ROM 15, whether to use a 16M-byte or 1M-byte address space, whether to set the initial value of data bus width to 8-bit or 16-bit, and the like. However, the invention is not specially limited to this construction. Multiple mode control terminals MODE are provided as required, and in this case, operation mode is determined by a combination of the states of input to these terminals.

When the reset state is released, the CPU 12 reads a start address, and carries out reset exception handling to start to read an instruction at this start address. The start address is stored in an area starting at address 0 though the invention is not specially limited to this construction. Thereafter, the CPU 12 sequentially executes instructions, beginning at the start address.

The DMAC 13 transfers data under the control of the CPU 12. The CPU 12 and the DMAC 13 perform read/write operation using internal buses and external buses, excluding each other. With respect to which should operate, the CPU 12 or the DMAC 13, the bus controller 14 carries out coordination.

In response to the operation of the CPU 12 or the DMAC 13, the bus controller 14 constructs a bus cycle. That is, it constructs a bus cycle based on an address, read signal, write signal, and bus size signal outputted from the CPU 12 or the DMAC 13. For example, when the CPU 12 outputs an address corresponding to the RAM 16 to the internal address bus IAB, one state is taken as bus cycle. Read/write operation is performed in one state regardless of byte/word size. When the CPU 12 outputs an address corresponding to the timer 17, SCI 18, or input/output port IOP1 to IOP9 to the internal address bus IAB, three states is taken as bus cycle. The contents in the internal address bus IAB is outputted to the internal address bus PAB, and read/write operation is performed in three states regardless of byte/word size. This control is carried out by the bus controller 14.

In the microcomputer 10 in this embodiment, the flash memory FMRY stores user programs, tuning information, data tables, and the like as appropriate. In the ROM 15, such system programs as OS are stored though the invention is not specially limited to this construction.

The memory portion 22 is connected with the internal buses IAB and IDB, and it is so constructed that it is accessible from the CPU 12 and the like. That is, the CPU 12 controls the following: setting of control information on a write/erase control register WEREG; supply of the control signal READ when read operation is instructed to read data from a memory cell MC; supply of address signals; supply of write data; and supply of redundant mode signals MD1. It also controls such processing as so-called software reset in which input of a system reset signal to the reset terminal RES by an external reset circuit or the like is controlled, and the reset circuit or the like is caused to generate a reset signal MD2. Read operation for erase verify or write verify is instructed by the CPU 12, and the read data is verified by the CPU 12.

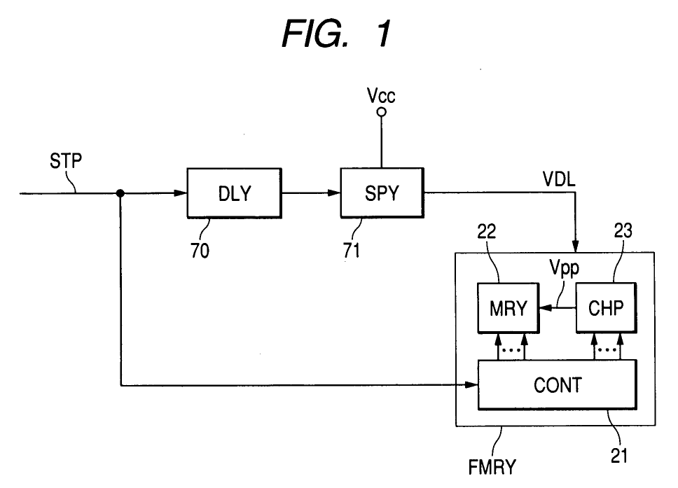

FIG. 1 illustrates an example of the configuration of the principal part of the single-chip microcomputer 10. The flash memory FMRY includes: the memory portion (MRY) 22; a charge pump (CHP) 23 for generating high voltage Vpp for write or erase in this memory portion 22; and a controller (CONT) 21 for controlling the operation of the memory portion 22 and the charge pump 23. When a power-off signal STP is asserted and brought into high level by the CPU 12, the controller 21 stops the operation of the charge pump 23. Further, the controller turns on a discharge path and thereby discharges electric charges for making the output voltage level of the charge pump 23 lowed from high voltage Vpp toward the voltage level of ground (or low potential-side power supply voltage). A delay circuit (DLY) 70 is provided. This delay circuit 70 has a function of delaying the power-off signal STP to be transmitted to the step-down circuit (SPY) 71 by a predetermined time. An amount of delay by the delay circuit 70 is set according to a time for making the output voltage of the charge pump 23 lowed from the voltage level of the high voltage Vpp to a sufficiently low level by discharging electric charges under control of the controller 21. This “sufficiently low level” means the output voltage level of the charge pump circuit 23 is lowered to same as or lower than the resistance voltage level of a MOS transistor in CPU 12 etc. Here, the charge pump 23 is an example of a high voltage generation circuit in the invention.

The power-off signal STP is delayed by the predetermined time by the delay circuit 70, and then transmitted to a step-down circuit (SPY) 71. This step-down circuit 71 steps down supply voltage supplied from the outside of the chip through the supply voltage terminal Vcc to an internal supply voltage VDL at a predetermined voltage level. When the power-off signal STP is asserted and brought to high level by the CPU 12, the step-down operation of the step-down circuit 71 is stopped. As mentioned above, the power-off signal STP is delayed by the predetermined time by the delay circuit 70. Therefore, a time equivalent to the delay time at the delay circuit 70 is required for the step-down operation of the step-down circuit 71 to be actually stopped after the power-off signal STP is asserted and brought to high level by the CPU 12.

According to techniques in the past, when power supply to a flash memory is interrupted while a charge pump is in operation and the logic for a path for discharging high voltage becomes inconsistent, there is a possibility that voltage is discharged through a low-breakdown voltage MOS transistor or the like. In this case, deterioration in or breakage of the MOS transistor can result.

With the construction describing the one embodiment of the inventions illustrated in FIG. 1, meanwhile, CPU 12 asserts the power-off signal STP; the controller 21 controls to stop generating the high voltage Vpp to the charge-pump circuit 23 in accordance with receiving the power-off signal STP; the charge-pump circuit 23 stops to generate the high voltage Vpp and discharges the electric charges from the charge-pump circuit 23 for lowing the output voltage of the charge-pump circuit 23; the delay circuit 70 delays to transfer the power-off signal STP to the step-down circuit 71 in the predetermined time; and the step-down circuit 71 receives the power-off signal STP after receiving the controller 21 in the predetermined time. The output voltage of the charge-pump circuit 23 is lowed to the “sufficiently low level” before receiving the power-off signal STP by the step-down circuit 71. Therefore, the MOS transistor, the resistance voltage of which is lower than it of the MOS transistor in the memory portion 22 or the charge-pump circuit 23, can be prevented from being deteriorated or broken due to power-off. The control circuit in the invention is so constructed that it includes the delay circuit 70.

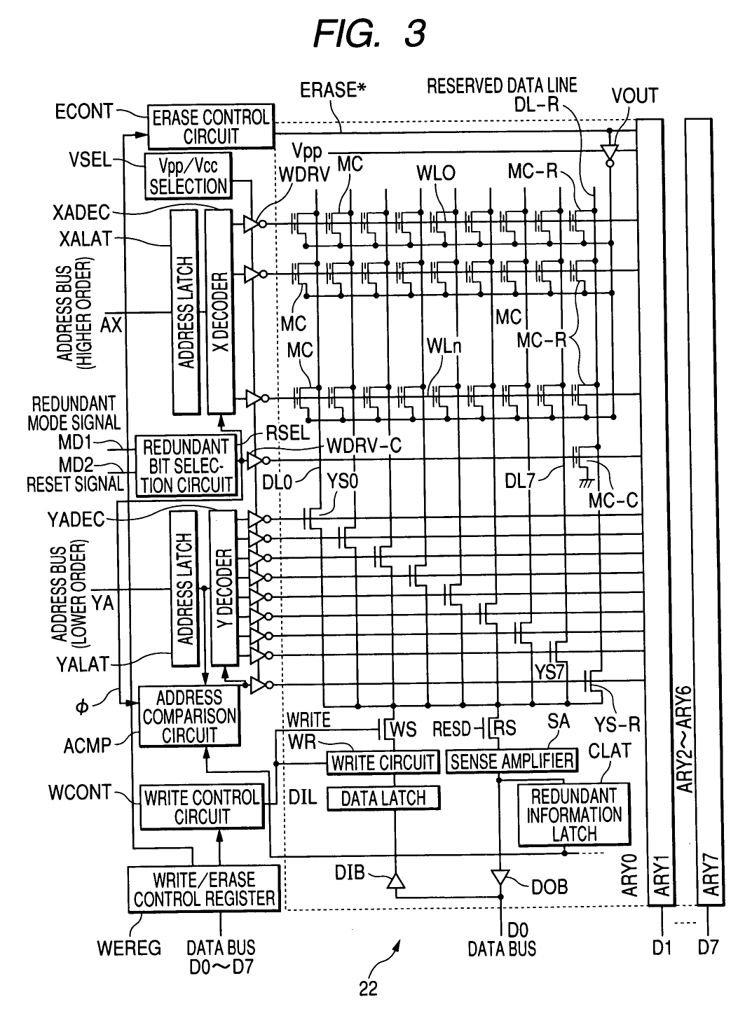

FIG. 3 illustrates a detailed example of the configuration of the memory portion 22.

The memory portion 22 has 8-bit data input/output terminals D0 to D7, and is provided with a memory array ARY0 to ARY7 with respect to each of the data input/output terminals. These memory arrays ARY0 to ARY7 are similarly constructed and they constitute one memory cell array.

In each of the memory arrays ARY0 to ARY7, memory cells MC, MC-R, and MC-C, constructed of insulated gate field effect transistors of two-layer gate structure, are arranged in a matrix pattern. The memory cells MC are memory cells to be remedied, and in cases where they are defective, they can be remedied. The memory cells MC-R are redundant memory cells and are substituted for memory cells MC remedied. The memory cells MC-C are memory cells for storing redundant information and store redundant information for specifying a memory cell MC to be substituted for by a memory cell MC-R. The disposition of the memory cells MC, MC-R, and MC-C is common to all the memory arrays ARY0 to ARY7. Therefore, the memory cells MC-R are arranged on a line in each memory array, and eight memory cells MC-C (equivalent to eight bits) in total are provided for all the memory arrays.

In the drawing, reference characters WL0 to WLn and WL-C denote word lines common to all the memory arrays ARY0 to ARY7. The control gates of memory cells arranged on the same line are respectively connected with corresponding word lines. The word lines WL-C are word lines dedicated to the memory cells MC-C. In the individual memory arrays ARY0 to ARY7, the drain regions of the memory cells MC, MC-R, and MC-C arranged on the same line are respectively connected with corresponding data lines DL0 to DL7 and DL-R. The data lines DL-R are reserved data lines dedicated to the memory cells MC-R and MC-C. The source regions of the memory cells MC and MC-R are connected in common with source lines SL. The source regions of the memory cells MC-C are brought to the ground level.

The source lines SL are supplied with high voltage Vpp for use in erasing from such a voltage output circuit VOUT as inverter circuit. The output operation of the voltage output circuit VOUT is controlled by an erase signal ERASE* outputted from an erase control circuit ECONT. (* indicates that the signal marked with it is a low-enable signal.) That is, during a period during which the erase signal ERASE* is at low level, the voltage output circuit VOUT supplies high voltage Vpp to the source lines SL. It thereby supplies high voltage required for erasing to the source regions of all the memory cells MC and MC-R. Thus, the entire memory portion 22 can be erased in a lump. The memory cells MC-C are excluded from the objects of this overall erasing.

Selection of a word line WL0 to WLn is carried out by an X address decoder XADEC decoding an X address signal AX taken in through an X address latch XALAT. Word drivers WDRV drive word lines based on a selection signal outputted from the X address decoder XADEC. In data read operation, the word drivers WDRV are operated using voltage Vcc, for example, 5V, supplied from a voltage selection circuit VSEL and ground potential, for example, 0V, as power supply. The word drivers drive a word line to be selected to the selection level by voltage Vcc, and keeps word lines not to be selected at the non-selection level, such as the ground potential. In data write operation, the word drivers WDRV are operated using voltage Vpp, for example, 12V, supplied from the voltage selection circuit VSEL and ground potential, for example, 0V, as power supply. The word drivers drive a word line to be selected to the high voltage level for writing, for example, 12V. In data erase operation, the output of the word drivers WDRV is brought to such a low voltage level as 0V.

The word lines WL-C are driven by a word driver WDRV-C that receives the output of a redundant bit selection circuit RSEL. Like the word drivers WDRV, it is supplied with drive voltage from the voltage selection circuit VSEL.

In the individual memory arrays ARY0 to ARY7, the data lines DL0 to DL7 and DL-R are connected in common with common data lines CD through Y selection switches YS0 to YS7 and YS-R. Switch control on the Y selection switches YS0 to YS7 is carried out by a Y address decoder YADEC decoding a Y address signal AY taken in through a Y address latch YALAT. The output selection signals of the Y address decoder YADEC are supplied in common to all the memory arrays ARY0 to ARY7. When any one of the output selection signals of the Y address decoder YADEC is brought to the selection level, the common data line CD of each of the memory arrays ARY0 to ARY7 is connected with one data line. The Y selection switches YS-R dedicated to the reserved data lines DL-R are selected based on the output of an address comparison circuit ACMP.

Data read from a memory cell MC to a common data line CD is supplied to a sense amplifier SA through a selection switch RS. It is amplified there and outputted to a data bus through a data output buffer DOB. Switching of the selection switches RS is controlled according to a read signal READ. Reference characters CLAT denotes a redundant information latch that stores redundant information read out of a memory cell MC-C. The number of redundant information latches CLAT equivalent to eight bits exist in all the memory arrays ARY0 to ARY7.

Write data supplied from an external source is taken in through a data input buffer DIB and is held at a data input latch DIL. When the data held at the data input latch DIL is “0,” a write circuit WR supplies high voltage for writing to the common data line CD through the selection switch WS. This high voltage for writing is supplied to the drain of a memory cell whose control gate has high voltage applied thereto through a word line, through any data line selected by the Y selection switches YS0 to YS7 and YS-R. As a result, data is written to that memory cell. Switching of the selection switches WS is controlled according to a control signal WRITE. Varied timing of writing and write operation procedures, such as voltage selection control, are controlled by a write control circuit WCONT. Instructions to this write control circuit WCONT and the erase control circuit ECONT are given by the control register WEREG for writing/erasing. Such instructions include: instructions of write operation and instructions of write verify operation to the write control circuit WCONT, and instructions of erase operation and instructions of erase verify operation to the erase control circuit ECONT. The control register WEREG is so constructed that it can be connected to data buses and control data can be written to it from an external source.

The control register WEREG has a Vpp bit, a PV bit, a P bit, and an E bit. The P bit is an instruction bit for write operation. The E bit is an instruction bit for erase operation. When the Vpp bit and the E bit are set, the erase control circuit ECONT that refers to the register controls internal operation for erasing, following a predetermined procedure. When the Vpp bit and the P bit are set, the write control circuit WCONT that refers to the register controls internal operation for writing, following a predetermined procedure. In the internal operation for erasing or writing the erase voltage or the write voltage is generated. The erase verify operation is an operation of performing read operation on an erased memory cell to verify whether the erasing has been completed or not. The write verify operation is an operation of reading write data from a written memory cell and comparing it with the write data to verify whether the writing has been completed or not. These verify operations are performed by an external CPU or data processor starting a read cycle for the flash memory.

Description will be given to a construction for defect redundancy.

The following are placed in the redundant information latches CLAT equivalent to eight bits: defect address A2 to A0 is placed in the lowest three bits and a redundant enable bit RE* is placed in the fourth bit. Each of the memory arrays ARY0 to ARY7 has eight data lines DL0 to DL7 and one reserved data line DL-R. Therefore, a defect address can be identified by the lowest three bits of an address signal. When the redundant enable bit RE* is at low level, that indicates the values of the lowest three bits of the redundant information latch CLAT are valid. That is, the lowest three bits of a redundant information latch CLAT is considered to be indicative of a defect address only when the redundant enable bit RE* is at low level.

Rough description will be given. The redundant bit selection circuit RSEL controls selection of a memory cell MC-C for storing redundant information. The address comparison circuit ACMP carries out control for selecting a reserved data line DL-R. The redundant bit selection circuit RSEL is supplied with the redundant mode signal MD1 and the reset signal MD2. The address comparison circuit ACMP is supplied with the output of the redundant bit selection circuit RSEL, the output of the Y address latch YLAT, and redundant information outputted from a redundant information latch CLAT. The memory portion 22 is brought into the following modes on a case-by-case basis: when the redundant mode signal MD1 is at the active level, it is brought into redundant program mode; when the reset signal MD2 is at the active level, it is brought into redundant information latch mode; and when the redundant mode signal MD1 and the reset signal MD2 are at the inactive level, it is brought into normal mode. In redundant program mode and in redundant information latch mode, the redundant bit selection circuit RSEL outputs a low-level control signal φ.

When the redundant mode signal MD1 is brought to the active level and the redundant program mode is established, the redundant bit selection circuit RSEL prohibits the word line selecting operation of the X address decoder XADEC by a low-level control signal φ. Instead, it controls selection of a word line WL-C dedicated to a memory cell MC-C for storing redundant information. It causes the address comparison circuit ACMP to prohibit the operation of the Y address decoder YADEC to select a Y selection switch YS0 to YS7. Instead, it causes the address comparison circuit ACMP to select a Y selection switch YS-R dedicated to a reserved data line DL-R. When the Vpp bit and the P bit of the write/erase control register WEREG are set to instruct write operation at this time, the following operation is performed: redundant information supplied from an external source to the data latch DIL of a memory array ARY0 to ARY7 is written to a memory cell MC-C.

When the reset signal MD2 is brought to the active level and the redundant information latch mode is established, the redundant bit selection circuit RSEL prohibits the word line selecting operation of the X address decoder XADEC by a low-level control signal φ. Instead, it controls selection of a word line WL-C dedicated to a memory cell MC-C for storing redundant information. It causes the address comparison circuit ACMP to prohibit the operation of the Y address decoder YADEC to select a Y selection switch YS0 to YS7 . Instead, it causes the address comparison circuit ACMP to select a Y selection switch YS-R dedicated to a reserved data line DL-R. Further, the redundant bit selection circuit RSEL brings the control signal READ to the selection level, activates the sense amplifier SA, and further causes the redundant information latch CLAT to perform latch operation. Thus, the redundant information stored in the memory cell MC-C is internally transferred to the redundant information latch CLAT. The redundant information internally transferred is outputted to the address comparison circuit ACMP. The reset signal MD2 is the power-on reset signal of a system to which the memory portion 22 is applied or the reset signal to the memory portion 22 though the invention is not specially limited to this construction.

In normal mode mentioned above, the address comparison circuit ACMP compares an address signal outputted from the Y address latch YALAT with a defect address outputted from a redundant information latch CLAT. When the result of comparison is agreement, in other words, when a memory cell MC to be remedied having defect is accessed, the following operation is performed: the operation of the Y address decoder YADEC to select a Y selection switch YS0 to YS7 is prohibited, and instead a Y selection switch YS-R dedicated to a reserved data line DL-R is selected. Thus, in read or write access by an address signal including the same low address bits as the defect address A2 to A0, a reserved data line DL-R is selected.

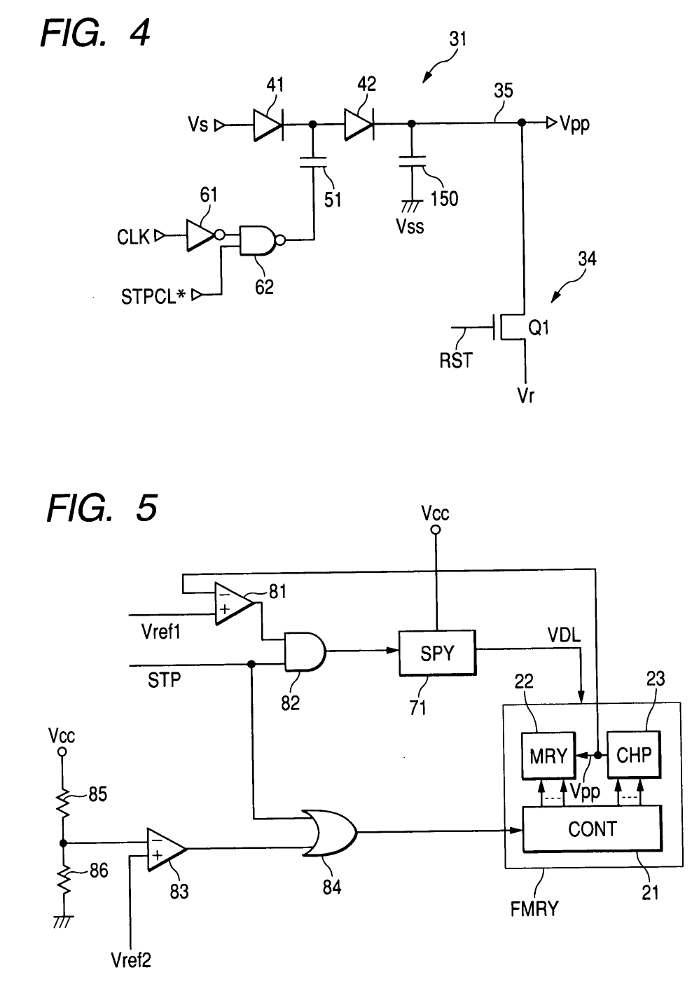

FIG. 4 illustrates an example of the configuration of the charge pump 23 in FIG. 1.

The charge pump 31 is so constructed that it includes: clamp diodes 41 and 42 connected in series; an inverter 61 that inverts a clock signal CLK; a NAND circuit 62 that obtains the inverted AND of an output signal of this inverter 61 and a clock stop signal STPCK*; a pumping capacitor (capacitor) 51 connected with the output terminal of the NAND circuit 62; and a load capacitor 150 connected with the output line 35 of the charge pump 31 and with low potential-side power supply Vss. In a state in which the clock stop signal STPCLK* is negated and brought to high level by the controller 21 illustrated in FIG. 1, the following operation is performed: the clock signal CLK is transmitted to the pumping capacitor 51, and as a result, pumping operation is performed. Output voltage POUT is generated by step-up operation relative to clamp voltage Vs. The clamp voltage Vs is voltage taken in through the supply voltage terminal Vcc though the invention is not specially limited to this construction. When the clock stop signal STPCL* is asserted and brought to low level by the controller 21 illustrated in FIG. 1, the clock signal CLK is not transmitted to the pumping capacitor. Therefore, pumping operation is not performed. The charge pump 31 is provided at its output with a reset circuit 34. This reset circuit 34 can be formed of one n-channel MOS transistor Q1. In cases where an n-channel MOS transistor Q1 is applied, the reset signal RST is active high. When the power-off signal STP is asserted and brought to high level, the controller 21 illustrated in FIG. 1 asserts and brings the clock stop signal STPCLK* to low level, and further asserts and brings the reset signal RST to high level. As the result of the reset signal RST being asserted and brought to high level, the n-channel MOS transistor Q1 is brought into conduction and the output line 35 of the charge pump 31 is forced to the level of reset voltage Vr. As a result, electric charges are discharged. The reset voltage Vr is so set that it is at the level of low potential-side power supply Vss though the invention is not specially limited to this construction.

According to the above-mentioned example, the following action and effect can be obtained.

The controller 21 is activated during the voltage level of the high voltage Vpp making lower in accordance with receiving the power-off signal STP from the CPU12. The charge-pump circuit 23 stops generating the high voltage Vpp and discharging the electrical charges charged in the capacitance for the output voltage of the charge-pump circuit 23 lowed. And the power-off signal STP is transferred via the delay circuit 70 to the step down circuit 71 after the predetermined time received the power-off signal STP by the controller 21. Before the step down circuit 71 receives the power-off signal STP, the output voltage of the charge-pump circuit 23 is lowered to the “sufficiently low level” or the ground level. Therefore, the MOS transistor, the resistance voltage of which is lower than it of the MOS transistor in the memory portion 22 or the charge-pump circuit 23, can be prevented from being deteriorated or broken due to power-off.

FIG. 5 illustrates another example of the configuration of the principal part of the single-chip microcomputer 10.

Great differences of the configuration illustrated in FIG. 5 from that illustrated in FIG. 1 are as follows: it is sensed that the output voltage Vpp of the charge pump 23 becomes equal to or lower than reference voltage Vref1, and the operation of the step-down circuit 71 is controlled based on the result of sensing; and the level of the supply voltage terminal Vcc is monitored, and high voltage Vpp generating operation is controlled based on the result of monitoring. The reference voltage Vref1 is set lower than the resistance voltage of the MOS transistor, which is lower than the resistance voltage of the MOS transistor in the memory portion 22 or the charge-pump circuit 23.

More specific description will be given. The single-chip microcomputer includes: a comparator 81 for comparing high voltage Vpp with reference voltage Vref1; and an AND gate 82 that obtains the logical product of an output signal of the comparator 81 and the power-off signal STP. It is so constructed that the operation of the step-down circuit 71 is controlled according to an output signal of this AND gate 82. When the power-off signal STP is asserted and brought to high level, electric charges arising from high voltage Vpp are discharged to ground under the control of the controller 21, and as a result, high voltage Vpp is lowered to a sufficiently low level. This is detected by the comparator 81, and the operation of the step-down circuit 71 is stopped based on the result of detection. Thus, the MOS transistor, the resistance voltage of which is lower than it of the MOS transistor in the memory portion 22 or the charge-pump circuit 23, can be prevented from being deteriorated or broken due to power-off. In this case, the comparator 81 is an example of the sensing circuit in the invention.

Resisters 85 and 86 are connected in series with each other, and thus an external supply voltage detection circuit capable of detecting the voltage level of the supply voltage terminal Vcc is formed. The result of detection at the resisters 85 and 86 is compared with reference voltage Vref2 at a comparator 83. The logical sum of this result of comparison and the power-off signal STP is obtained at an OR gate 84, and the operation of the memory portion 22 and the charge pump 23 is controlled according to an output signal of the OR gate 84. With this construction, the following is implemented: when the voltage level of the supply voltage terminal Vcc is lowered, generation of high voltage Vpp is swiftly stopped through the operation control of the controller 21. Large capacitance exists in the transmission path of the step-down circuit 71 for output voltage VDL. The output voltage VDL of the step-down circuit 71 is kept at a predetermined voltage level until high voltage Vpp is lowered to a predetermined voltage level according to an output signal of the comparator 83.

Up to this point, concrete description has been given to the invention made by the present inventors. However, the invention is not limited to the foregoing, and various modifications can be made without departing from the scope of the invention, needless to add.

The above description takes, as an example, cases where the invention made by the inventors is applied to a single-chip microcomputer, which belongs to the field of utilization underlying the invention. The invention is not limited to this, and is widely applicable to various semiconductor integrated circuits.

The invention can be applied on condition that a memory portion obtained by arranging electrically rewritable nonvolatile memory cells in array is included.

What is claimed is:

1. A semiconductor integrated circuit comprising:
a semiconductor memory including a memory portion constituted by arranging electrically rewritable nonvolatile memory cells in array and a high voltage generation circuit capable of generating high voltage supplied to the memory portion; and
a power supply circuit for generating supply voltage for operating the semiconductor memory,
in which the semiconductor integrated circuit is capable of interrupting power supply from the power supply circuit to the semiconductor memory according to a power-off signal,
the semiconductor integrated circuit further comprising a control circuit for interrupting power supply from the power supply circuit to the semiconductor memory after the output voltage level of the high voltage generation circuit is lowered according to the power-off signal.

2. The semiconductor integrated circuit according to claim 1,
wherein the control circuit includes a delay circuit for delaying the power-off signal so that power supply from the power supply circuit to the semiconductor memory is interrupted after the output voltage level of the high voltage generation circuit is lowered according to the power-off signal.

3. The semiconductor integrated circuit according to claim 2,
wherein an amount of delay of the power-off signal at the delay circuit is set based on the time from the time when the power-off signal is asserted to the time when the output voltage level of the high voltage generation circuit is lowered to a predetermined voltage level.

4. A semiconductor integrated circuit comprising:
a semiconductor memory including a memory portion constituted by arranging electrically rewritable nonvolatile memory cells in array and a high voltage generation circuit capable of generating high voltage supplied to the memory portion; and
a power supply circuit for generating supply voltage for operating the semiconductor memory,
in which the semiconductor integrated circuit is capable of interrupting power supply from the power supply circuit to the semiconductor memory according to a power-off signal,
the semiconductor integrated circuit further including:
a sensing circuit capable of sensing that the output voltage of the high voltage generation circuit has been lowered to a predetermined voltage level or below according to the power-off signal; and
a logic gate for transmitting the power-off signal to the power supply circuit based on the result of sensing at the sensing circuit.

5. The semiconductor integrated circuit according to claim 4,
wherein the power supply circuit steps down external supply voltage supplied from external of the semiconductor integrated circuit to thereby generate supply voltage for operating the semiconductor memory.

6. The semiconductor integrated circuit according to claim 5 comprising:
an external supply voltage detection circuit capable of detecting external supply voltage supplied from external of the semiconductor integrated circuit; and
a determination circuit capable of determining drop in the external supply voltage based on the result of detection at the external supply voltage detection circuit,
wherein power supply to the semiconductor memory is interrupted based on an output signal of the determination circuit or the power-off signal.

7. A microcomputer comprising:
a semiconductor memory including a memory portion constituted by arranging electrically rewritable nonvolatile memory cells in array and a high voltage generation circuit capable of generating high voltage supplied to the memory portion;
a power supply circuit for generating supply voltage for operating the semiconductor memory; and
a central processing unit capable of accessing the semiconductor memory,
in which the microcomputer is capable of interrupting power supply from the power supply circuit to the semiconductor memory according to a power-off signal,
the microcomputer further comprising:
a sensing circuit capable of sensing that the output voltage of the high voltage generation circuit has been lowered to a predetermined voltage level, which is same as or lower than a resistance voltage of a MOS transistor in said central processing unit, or below according to the power-off signal; and
a logic gate for transmitting the power-off signal to the power supply circuit based on the result of sensing at the sensing circuit.

8. The microcomputer according to claim 7,
wherein the power supply circuit steps down external supply voltage supplied from external of the semiconductor integrated circuit to thereby generate supply voltage for operating the semiconductor memory.

9. The microcomputer according to claim 8 comprising:
an external supply voltage detection circuit capable of detecting external supply voltage supplied from external of the semiconductor integrated circuit; and
a determination circuit capable of determining drop in the external supply voltage based on the result of detection at the external supply voltage detection circuit,
wherein power supply to the semiconductor memory is interrupted based on an output signal of the determination circuit or the power-off signal.
